(19) United States
(12) Patent Application Publication
(10) Pub. No.: US 2016/0299182 A1
(43) Pub. Date: Oct. 13, 2016

(54) ELECTROMAGNETIC INTERFERENCE WAVE MEASUREMENT DEVICE, ELECTROMAGNETIC INTERFERENCE WAVE MEASUREMENT METHOD AND NON-TRANSITORY COMPUTER-READABLE MEDIUM

(71) Applicant: NEC CORPORATION, Minato-ku, Tokyo (JP)

(72) Inventor: Kenta TSUKAMOTO, Tokyo (JP)

(21) Appl. No.: 15/035,534

(22) PCT Filed: Jun. 10, 2014
(86) PCT No.: PCT/JP2014/003075

§ 371 Date: May 10, 2016

(30) Foreign Application Priority Data
Nov. 14, 2013 (JP) 2013-235651

(51) Int. Cl. G01R 29/08

(52) U.S. Cl. CPC G01R 29/0814

(57) ABSTRACT

In the present invention, an electromagnetic interference wave measurement device (100) is provided at least with a mask setting unit (103) for setting an amplitude probability distribution mask by converting a bit error rate allowed by an arbitrarily specified desired communication system to an amplitude probability distribution mask, an acquisition unit (101) for collecting time-series measured data for electromagnetic interference waves emitted from an object under measurement, an amplitude probability distribution calculation unit (102) for calculating an amplitude probability distribution indicating the measured results on the basis of the measured data collected by the acquisition unit (101) for each predetermined time interval, and an output unit (106) for outputting the amplitude probability distribution mask set by the mask setting unit (103) and the amplitude probability distribution calculated by the amplitude probability distribution calculation unit (102). As a result, the present invention is capable of providing an electromagnetic interference wave measurement device capable of accurately determining the influence of electromagnetic interference waves emitted from an object under measurement on a desired communication system.

### TECHNICAL FIELD

The present invention relates to an electromagnetic interference wave measurement device, an electromagnetic interference wave measurement method, and an electromagnetic interference wave measurement program and, in particular, to an electromagnetic interference wave measurement device, an electromagnetic interference wave measurement method, and an electromagnetic interference wave measurement program that collect data on electromagnetic waves emitted from an object under measurement and use the data for an evaluation of the impact of electromagnetic interference waves on a communication system.

### BACKGROUND ART

While the demand for the use of radio waves in mobile communications is increasing these years, electromagnetic interference from interference waves in radio frequency bands used in mobile communications is frequently causing radio communication disturbance in networks such as mobile phone networks and wireless LANs (Local Area Networks) and disturbance of reception of television and radio broadcasting and the like. Such interference waves are emitted from sources such as various types of electronic devices and cause electromagnetic disturbance with nearby radio communication devices or with electronic devices themselves that emit interference waves. There is therefore a strong demand for preventing radiation of interference waves generated by electronic devices in order to ensure communication quality.

In an evaluation of such ElectroMagnetic Interference waves (EMI), spectrum analyzers are used to measure the maximum and mean values of strengths of interference waves of measured frequencies. However, many interference waves often have characteristics that change with time and it is therefore difficult to accurately evaluate electromagnetic interference waves by evaluation methods that use a single parameter.

A well-known method for evaluating changes in interference waves with time and the impact of interference waves on communications is amplitude probability distribution measurement. Amplitude Probability Distribution (APD) is a statistical parameter that can be obtained based on acquired measured time-series data on interference wave amplitude values as the ratio of the time Tᵢ during which an amplitude envelope is greater than a predetermined amplitude value Eₖ to the total measurement time T as shown in Equation (1) given below. The amplitude probability distribution is useful as the measure for an evaluation of an interference wave of digital noise because the amplitude probability distribution represents the relationship between the frequency of occurrences of noise and amplitude strength. By measuring the amplitude probability distribution, the impact of noise that changes with time can be determined.

$$\begin{matrix}[ Math . 1 ] & \\ APD ( {E}_{k} ) = \frac{{\sum }_{i = 1}^{h} {T}_{i} ( {E}_{k} )}{T} & ( 1 )\end{matrix}$$

The amplitude probability distribution is highly correlated with a bit error rate (BER) before error correction in an evaluation of communications as described in PTL 1, Japanese Laid-open Patent Publication No. 2011-135161 “OFDM Wireless Communication Terminal”. Therefore, the impact of an interference wave being measured on a nearby digital wireless communication system can be evaluated based on an amplitude probability distribution under predetermined particular conditions. The particular conditions here include that the level of internal noise within a measuring instrument is equal to the level of internal noise within a receiver, that the receiver uses synchronous detection, and that the communication bandwidth of the communication system is equal to the measurement bandwidth, among other conditions.

PTL 2, Japanese Patent Publication No. 3374154 “Spectrum Analyzer”, discloses a spectrum analyzer that has the function of measuring amplitude probability distributions as a device that measures amplitude probability distributions of interference waves. PTL 3, Japanese Laid-open Patent Publication No. 2008-039762 “Electromagnetic Interference Measurement System and Selecting System Using the Same”, proposes an electromagnetic interference measurement system that divides an interfering wave across a wide band into a plurality of frequency bands, measures amplitude probability distributions in the frequency bands at a time, and outputs the result of the measurement as display data. The spectrum analyzer that has the function of measuring an amplitude probability distribution and the wave measurement device that has the function of measuring a CCDF (Complementary Cumulative Distribution Function), which is practically equivalent to an amplitude probability distribution as described in PTLs 2 and 3, measure the amplitude strength of an interfering wave in a set measurement bandwidth and obtain an amplitude probability distribution or CCDF based on arithmetic processing.

### CITATION LIST

### Patent Literature

PTL 1: Japanese Laid-open Patent Publication No. 2011-135161 (pp. 6-7)

PTL 2: Japanese Patent Publication No. 3374154 (pp. 6-9)

PTL 3: Japanese Laid-open Patent Publication No. 2008-039762 (pp. 3-6)

### Disclosure of Invention

### Technical Problem

The wave measurement devices according to the related art described in PTLs 1 to 3 accurately measure the amplitude probability distributions of electromagnetic interference waves.

However, in order to evaluate the impact of an electromagnetic interference wave on a communication system, comparison with a desired communication performance value that provides an allowable limit value is required. An example of the communication performance value is a desired bit error rate at a predetermined signal intensity. In order to evaluate the impact of an electromagnetic interference wave on a communication system immediately after measurement by using an amplitude probability distribution of the electromagnetic interference wave measured by the measurement device described in PTL 1 or 3, data such as a desired communication performance value (such as a bit error rate) that provides an allowable limit value of the impact needs to be converted into amplitude probability distribution data in advance.

Furthermore, in a wireless communication system that switches from one modulation scheme to another among a plurality of modulation schemes in accordance with a communication environment such as LTE (Long Term Evolution), a desired allowable communication performance value varies depending on the modulation scheme used. Accordingly, it is more difficult to accurately determine the impact of an EMI wave on the communication system.

### Object of Invention

The present invention has been made in light of the problems described above and an object of the present invention is to provide an electromagnetic interference wave measurement device, an electromagnetic interference wave measurement method and an electromagnetic interference measurement program that enable accurate determination of the impact of an electromagnetic interference wave emitted from an object under measurement on a desired communication system.

### Solution to Problem

To solve the problem, an electromagnetic interference wave measurement device, an electromagnetic interference wave measurement method, and an electromagnetic interference wave measurement program according to the present invention has the following main characteristic configurations.

(1) The electromagnetic interference wave measurement device of the present invention is an electromagnetic interference wave measurement device which measures an electromagnetic interference wave emitted from an object under measurement and evaluates electromagnetic interference, the electromagnetic interference wave measurement device including:

a mask setting unit for converting a bit error rate allowed in an arbitrarily specified desired communication system into an amplitude probability distribution mask and setting the amplitude probability distribution mask resulting from the conversion;

an acquisition unit for collecting time-series measured data concerning an electromagnetic interference wave being emitted from the object under measurement;

an amplitude probability distribution calculation unit for calculating an amplitude probability distribution relating to the electromagnetic interference wave based on the measured data collected by the acquisition unit at predetermined time intervals; and

an output unit for outputting the amplitude probability distribution mask set by the mask setting unit and the amplitude probability distribution calculated by the amplitude probability distribution calculation unit.

(2) The electromagnetic interference wave measurement method of the present invention is an electromagnetic interference wave measurement method for measuring an electromagnetic interference wave emitted from an object under measurement and evaluating electromagnetic interference, the electromagnetic interference wave measurement method including:

a mask setting step of converting a bit error rate allowed in an arbitrarily specified desired communication system into an amplitude probability distribution mask and setting the amplitude probability distribution resulting from the conversion;

an acquisition step of collecting time-series measured data concerning an electromagnetic interference wave being emitted from the object under measurement;

an amplitude probability distribution calculation step of calculating an amplitude probability distribution indicating a result of measurement based on the measured data collected at predetermined time intervals; and

an output step of outputting the amplitude probability distribution mask set at the mask setting step and the amplitude probability distribution calculated at the amplitude probability distribution calculation step.

(3) The electromagnetic interference wave measurement program of the present invention at least causes a computer to execute the electromagnetic interference wave measurement method according to above-described (2).

### Advantageous Effect of Invention

An electromagnetic interference wave measurement device, an electromagnetic interference wave measurement method and an electromagnetic interference wave measurement program according to the present invention include the function of displaying an amplitude probability distribution mask calculated from an allowable value of communication performance to enable accurate determination of the impact of an electromagnetic interference wave emitted from an object under measurement on a desired communication system.

### BRIEF DESCRIPTION OF DRAWINGS

FIG. 1 is a block diagram illustrating an exemplary configuration of a first exemplary embodiment of an electromagnetic interference wave measurement device according to the present invention.

FIG. 2 is an image diagram illustrating an exemplary image of an output from the electromagnetic interference wave measurement device according to the first exemplary embodiment of the present invention.

FIG. 3 is a characteristics graph illustrating theoretical values of bit error rates in different modulation schemes, where interference waves are Gaussian noise.

FIG. 4 is an image diagram illustrating an exemplary image of an output from an electromagnetic interference wave measurement device according to a second exemplary embodiment of the present invention.

FIG. 5 is a block diagram illustrating an exemplary configuration of a fourth exemplary embodiment of an electromagnetic interference wave measurement device according to the present invention.

### DESCRIPTION OF EMBODIMENTS

Preferable modes of an electromagnetic interference wave measurement device, an electromagnetic interference wave measurement method, and an electromagnetic interference wave measurement program according to the present invention will be described below with reference to the accompanying drawings. While an electromagnetic interference wave measurement device and an electromagnetic interference wave measurement method according to the present invention will be described below, it is needless to say that the electromagnetic interference wave measurement method may be implemented as a computer-executable electromagnetic interference wave measurement program or such an electromagnetic interference wave measurement program may be recorded on a computer-readable recording medium.

### Features of Invention

Prior to the description of exemplary embodiments of the present invention, an overview of features of the present invention will be provided first. A main feature of the present invention is that the function of displaying an amplitude probability distribution mask calculated from an allowable value of communication performance is provided to enable accurate determination of the impact of an electromagnetic interference wave emitted from an object under measurement on a desired communication system. Accordingly, a measurer (a user) can immediately determine whether the electromagnetic interference wave emitted from the object under measurement is allowable in terms of communication performance of the desired communication system and can quickly take measures. Furthermore, the present invention enables a front-loading design and development of electronic devices and design and development of high-quality radio communication devices that ensure communication performance.

More specifically, an electromagnetic interference wave measurement device according to the present invention is mainly characterized by including at least a mask setting unit which converts a bit error rate in an arbitrarily specified desired communication scheme into an amplitude probability distribution mask and sets the amplitude probability distribution mask, an acquisition unit which collects time-series measured data concerning an electromagnetic interference wave emitted from an object under measurement, an amplitude probability distribution calculation unit which calculates an amplitude probability distribution representing a result of measurement based on the measured data collected by the acquisition unit at predetermined time intervals, and an output unit which outputs the amplitude probability distribution mask set by the mask setting unit and the amplitude probability distribution calculated by the amplitude probability distribution calculation unit.

### EMBODIMENTS

Exemplary embodiments of an electromagnetic interference wave measurement device according to the present invention will be described below in detail with reference to the drawings. It is needless to say that reference numerals in the drawings and the following description are assigned to elements for convenience as examples for helping the understanding of the present invention and are not intended to limit the present invention to the exemplary embodiments illustrated in the drawings.

### First Exemplary Embodiment

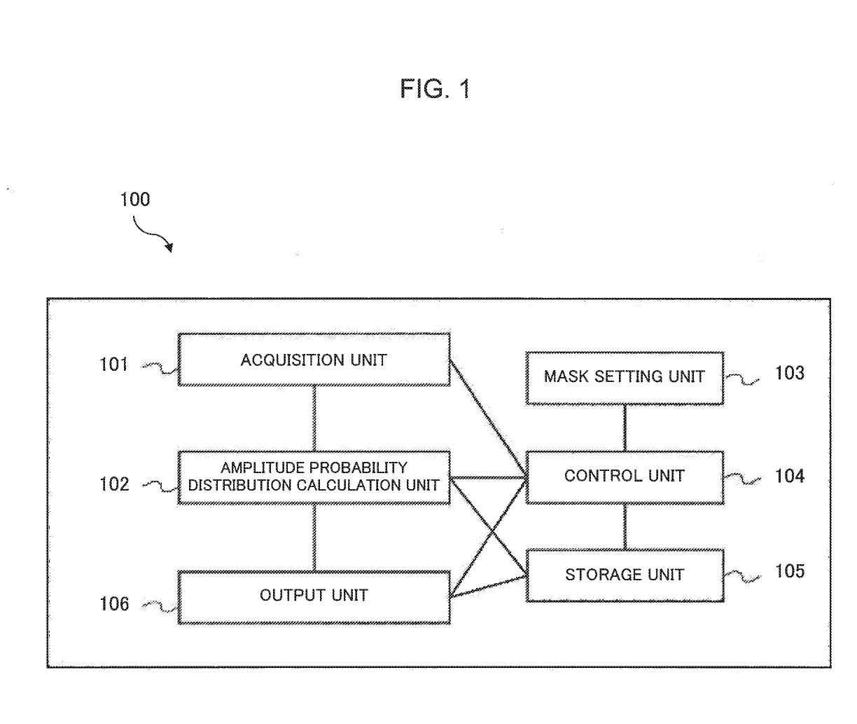

As a first exemplary embodiment of the present invention, an exemplary preferable configuration of an electromagnetic interference wave measurement device including the function of presenting an amplitude probability distribution mask converted from an allowed bit error rate as communication performance will be described first with reference to FIG. 1. FIG. 1 is a block diagram illustrating an exemplary configuration of an electromagnetic interference wave measurement device according to the first exemplary embodiment of the present invention.

The electromagnetic interference wave measurement device 100 illustrated in FIG. 1 includes at least an acquisition unit 101, an amplitude probability distribution calculation unit 102, a mask setting unit 103, a control unit 104, a storage unit 105, and an output unit 106.

The acquisition unit 101 is acquisition means for measuring an electromagnetic wave including a disturbance such as electromagnetic interference wave and produces data from the measured electromagnetic wave. A receiving interface used in the measurement may be a voltmeter, a field-strength meter, a spectrum analyzer or the like that is capable of measuring the amplitudes of electromagnetic waves of individual frequencies. The acquisition unit 101 includes the function of repeating sampling over a predetermined period of time to measure the frequency and the amplitude of an electromagnetic wave at each individual measurement location and the function of converting changes in the waveform of an electromagnetic interference wave emitted from an object under measurement with time into time-series digital measured data. The converted time-series measured data is made divisible into segments each of which corresponds to a predetermined period of time and is sent to the amplitude probability distribution calculation unit 102.

The amplitude probability distribution calculation unit 102 is amplitude probability distribution calculation means for performing a process for calculating an amplitude probability distribution from time-series measured data collected as a result of measurement by the acquisition unit 101. The amplitude probability distribution calculated by the amplitude probability distribution calculation unit 102 is sent to the output unit 106 and is also stored in the storage unit 105.

The mask setting unit 103 is mask setting means for converting, depending on a set condition, a bit error rate allowed in a communication system desired by a user into an amplitude probability distribution mask and setting the amplitude probability distribution mask resulting from the conversion. The amplitude probability distribution mask resulting from the conversion by the mask setting unit 103 is sent to the output unit 106 and is also stored in the storage unit 105. It is desirable that setting conditions for the mask setting unit 103 can be determined by the user selecting a desired communication system or modulation scheme and inputting a bit error rate allowed in the desired communication system or modulation scheme through an external input terminal.

Note that a bit error rate allowed in a communication system or a modulation scheme may indeed be a fixed value prescribed in a standard or the like instead of being input by the user. For example, in the field of digital terrestrial broadcasting, a bit error rate that allows acceptable viewing before error correction is at most 2×10⁻⁴ or less at a specified CN (Channel to Noise) ratio. In the case of WCDMA (registered trademark (Wideband Code Division Multiple Access)), the minimum receiver sensitivity at an error rate of 10⁻³ or less is specified by the 3GPP (the 3rd Generation Partnership).

For communication systems for which required levels are specified in standards in this way, a configuration is desirable in which amplitude probability distribution masks converted from the required bit error rates are held in the storage unit 105 in advance and, in response to a user selecting a desired communication system, the mask setting unit 103 reads from the storage unit 105, the relevant amplitude probability distribution mask for the communication system and sets the amplitude probability distribution mask, so that the amplitude probability distribution mask can be presented at the same time as an amplitude probability distribution representing a result of measurement of an electromagnetic interference wave from an object under measurement.

Under conditions where it is inappropriate to convert a bit error rate into an amplitude probability distribution mask in the mask setting unit 103, such as when a measurement bandwidth differs from the communication bandwidth of the communication system, a process such as presenting an error message to the user to indicate that conversion into an amplitude probability distribution is inappropriate may be executed.

The output unit 106 displays an amplitude probability distribution calculated by the amplitude probability distribution calculation unit 102 based on a result of measurement by the acquisition unit 101 and an amplitude probability distribution mask set by the mask setting unit 103 by conversion on an internal display device. Alternatively, the output unit 106 prints the amplitude probability distribution and amplitude probability distribution mask on a printer and outputs the amplitude probability distribution and amplitude probability distribution mask on an external display device as required. The amplitude probability distribution and the amplitude probability distribution mask may be output in any method that allows the user to identify them and may be output through a display device or a printer, for example. The amplitude probability distribution and the amplitude probability distribution mask may be stored in the storage unit 105 so that the amplitude probability distribution and amplitude probability distribution mask can be accessed from another information processing system and may be made available to the information processing system as well. The control unit 104 controls the acquisition unit 101, the amplitude probability distribution calculation unit 102, the mask setting unit 103, the storage unit 105 and the output unit 106 to enable the units to perform the functions described above. For example, an amplitude probability distribution mask set by the mask setting unit 103 is output to the storage unit 105 and to the output unit 106 through the control unit 104.

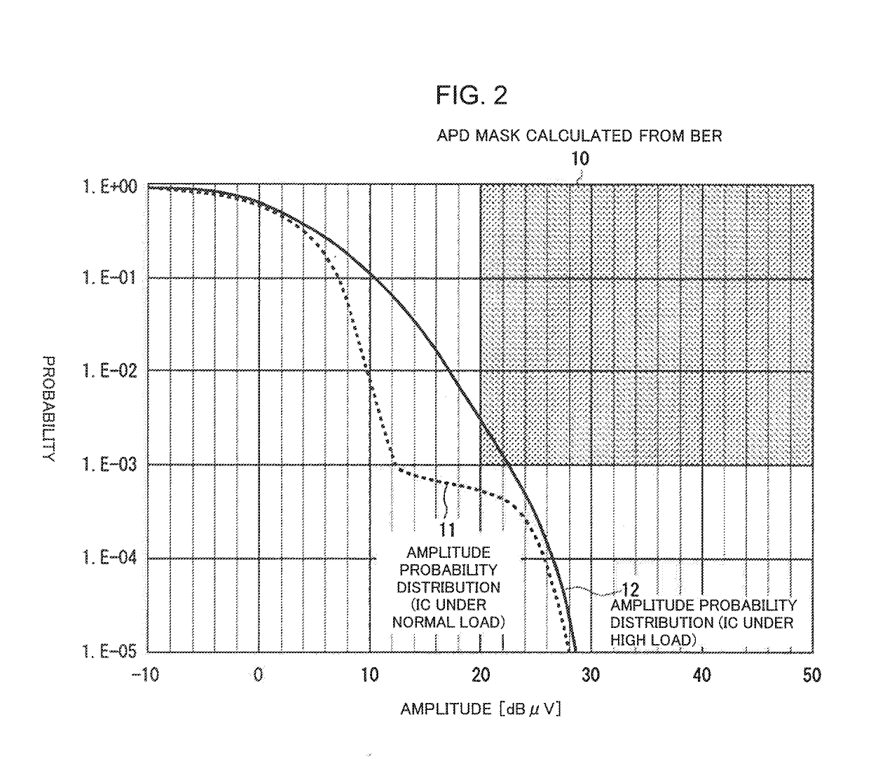

FIG. 2 is a sample diagram illustrating an example of data displayed by the output unit 106 that has received an amplitude probability distribution calculated by the amplitude probability distribution calculation unit 102 and an amplitude probability distribution mask generated by the mask setting unit 103 in the electromagnetic interference wave measurement device according to the first exemplary embodiment of the present invention; the horizontal axis represents amplitude and the vertical axis represents probability. Illustrated in the sample diagram in FIG. 2 are: an amplitude probability distribution 11 that is a result of measurement when the load on an IC (Integrated Circuit) that is a source of an interference wave that can interfere with a mobile radio communication terminal is normal (IC under normal load) and an amplitude probability distribution 12 that is a result of measurement when the load on the IC is high (IC under high load) as amplitude probability distributions which are results of measurement of the mobile radio communication terminal under different operating conditions. In addition, an APD (Amplitude Probability Distribution) mask calculated from a bit error rate (BER) allowed in the mobile radio communication terminal, i.e. an amplitude probability distribution mask 10 is illustrated in FIG. 2.

It can be seen from the amplitude probability distribution 11 and the amplitude probability distribution 12 in FIG. 2 that in the same mobile radio communication terminal, the interference wave characteristic varies depending on the load on the IC, which is the source of the interference waves. The amplitude probability distribution mask 10 in the upper right corner of FIG. 2 is set by converting a bit error rate (BER) allowed in the communication system selected/input by the user, i.e. the communication system that uses the mobile radio communication terminal.

In the example in FIG. 2, the curve of the amplitude probability distribution 12 when the IC that is the interference wave source is under high load includes a segment that overlaps the amplitude probability distribution mask 10. From the presence of the segment of the curve of the amplitude probability distribution 12 that overlaps the amplitude probability distribution mask 10, it can be estimated that the bit error rate can degrade to a value equal to or exceeding the allowable limit value. The user who has identified this state can take measures against EMI (Electro-Magnetic Interference) on the IC or can perform control to prevent a high load from being applied to the IC.

Since measured amplitude probability distributions and a set amplitude probability distribution mask are displayed in the first exemplary embodiment as described above, the user can quickly and readily see how much impact of an electromagnetic interference wave emitted from an object under measurement has on the desired communication system and can effectively use the result for taking measures against EMI and other purposes. In addition, since the user can estimate a bit error rate characteristic at an early stage of electromagnetic interference wave measurement, a front-loading design and development of a product protected against EMI is made possible and the costs of the product can be reduced.

### Second Exemplary Embodiment

A second exemplary embodiment of the present invention is an example in which the mask setting unit 103 in the electromagnetic interference wave measurement device 100 illustrated in FIG. 1 is configured in a more preferable manner. As described in the description of the first exemplary embodiment, the mask setting unit 103 includes the function of converting a desired allowed bit error rate into an amplitude probability distribution mask and setting the amplitude probability distribution mask. The second exemplary embodiment is characterized in that the mask setting unit 103 calculates amplitude probability distribution masks for a plurality of modulation schemes and an output unit 106 outputs the amplitude probability distribution masks for the plurality of modulation schemes at the same time.

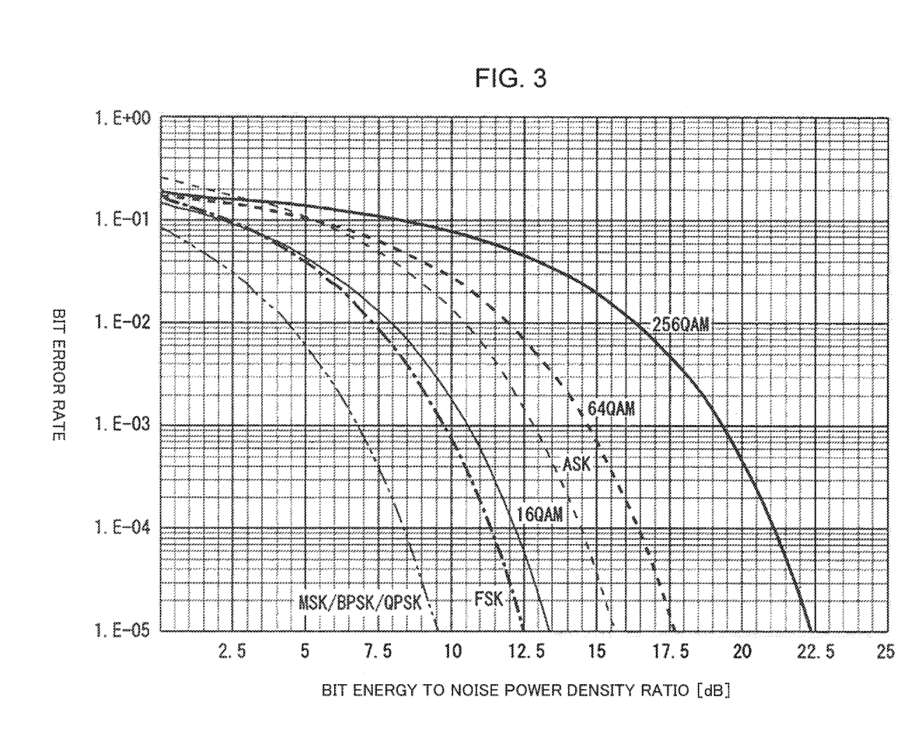

FIG. 3 is a characteristics diagram illustrating theoretical values of bit error rates in different modulation schemes, where interference waves are considered to be additive Gaussian noise, and illustrates a graph of allowed bit error rates theoretically calculated for the individual modulation schemes, in which the horizontal axis represents bit energy to noise power density ratio (Eb/No) and the vertical axis represents bit error rate (BER).

As illustrated in FIG. 3, bit error characteristics vary among different modulation schemes, which include the MSK (Minimum Shift Keying)/BPSK (Binary Phase Shift Keying)/QPSK (Quadrature Phase Shift Keying) modulation scheme, the FSK (Frequency Shift Keying) modulation scheme, the 16-QAM (Quadrature Amplitude Modulation) modulation scheme, the ASK (Amplitude-Shift Keying) modulation scheme, the 64-QAM modulation scheme, and the 256-QAM modulation scheme, in the order of increasing allowed bit error rate at the same Eb/No. Accordingly, amplitude probability distribution masks, which are set by converting from the allowed bit error rates, have shapes that vary depending on the modulation schemes. It can be therefore useful to present a plurality of amplitude probability distribution masks corresponding to a plurality of modulation schemes in a wireless communication system that uses adaptive modulation schemes such as LTE (Long Term Evolution) which switches from one modulation scheme to another in accordance with a communication environment.

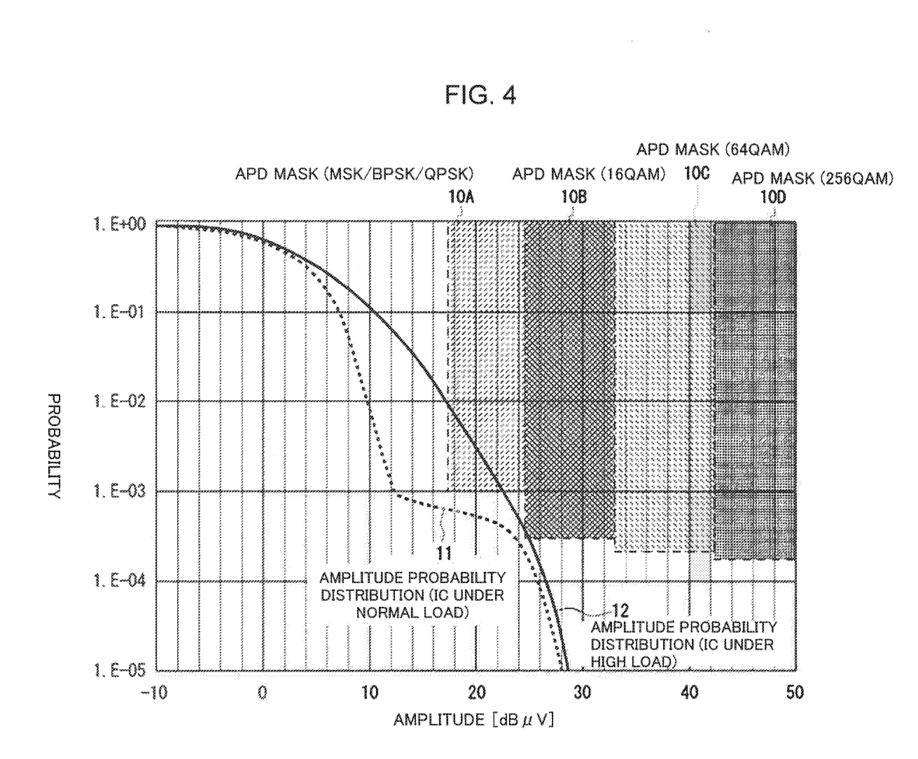

FIG. 4 is a sample diagram illustrating an example of data displayed by the output unit 106 that has received amplitude probability distributions calculated by an amplitude probability distribution calculation unit 102 and amplitude probability distribution masks generated by the mask setting unit 103 in the electromagnetic interference wave measurement device according to the second embodiment of the present invention. As in FIG. 2, the horizontal axis represents amplitude and the vertical axis represents probability. As in FIG. 2, illustrated in the sample diagram in FIG. 4 are: an amplitude probability distribution 11 that is a result of measurement when the load on an IC (Integrated Circuit) that is a source of an interference wave that can interfere with a mobile radio communication terminal is normal (IC under normal load) and an amplitude probability distribution 12 that is a result of measurement when the load on the IC is high (IC under high load) as amplitude probability distributions which are results of measurement of the mobile radio communication terminal. On the other hand, unlike the sample diagram in FIG. 2, the sample diagram in FIG. 4 simultaneously plays a plurality of amplitude probability distribution masks calculated from bit error rates (BER) allowed on the mobile radio communication terminal for individual modulation schemes that are adaptively used in the mobile radio communication terminal.

For example, as the amplitude probability distribution masks, four amplitude probability distribution masks, an amplitude probability distribution mask 10A that is used when the MSK/BPSK/QPSK modulation scheme is used on the mobile radio communication terminal, an amplitude probability distribution mask 10B that is used when the 16-QAM modulation scheme is used on the mobile radio communication terminal, an amplitude probability distribution mask 10C that is used when the 64-QAM modulation scheme is used on the mobile radio communication terminal, and an amplitude probability distribution mask 10D that is used when the 256-QAM modulation scheme is used on the mobile radio communication terminal, are displayed at the same time. However, the amplitude probability distribution masks illustrated in FIG. 4 are illustrated by way of example for facilitating the understanding of how different amplitude probability distribution masks for different modulation schemes and operating environments are displayed. Therefore, amplitude probability distribution masks for modulation schemes in practice may be displayed in an arrangement different from the example in FIG. 4.

Because displaying a plurality of amplitude probability distribution masks at the same time allows the user to evaluate the acceptability of an allowable value for each modulation scheme at the same time, the user can obtain useful information about not only measures against EMI but also system control for selecting a modulation scheme.

In practice, a transmitter and a receiver of a communication system of interest are provided and degradation of the communication performance of the communication system due to an interfering wave from an object under measurement is evaluated while the receiver is receiving a transmission radio wave transmitted from the transmitter and an interference wave emitted from the object under measurement at the same time. Note that if degradation of the communication performance caused by an interference wave emitted from a radio device itself (intra EMI) is to be evaluated, the receiver is the object under measurement and the interference source to be evaluated. In such a case, conventionally, measurement needs to be made over again each time a condition of the communication system, such as a modulation scheme, is changed. In contrast, the interference wave measurement device according to the second exemplary embodiment has the advantage that the impacts of an interference wave on a communication system in different modulation schemes can be determined at a time by making an evaluation that uses the simple measurement system that uses only an interference wave characteristic of an object under measurement.

### Third Exemplary Embodiment

A third exemplary embodiment of the present invention is an example that differs from the second exemplary embodiment in that the mask setting unit 103 in the electromagnetic interference wave measurement device illustrated in FIG. 1 is configured in a preferable manner. Similar to the mask setting units 103 in the first and second exemplary embodiments, the mask setting unit 103 of the third exemplary embodiment includes the function of converting a desired allowed bit error rate into an amplitude probability distribution mask and setting the amplitude probability distribution mask. The third exemplary embodiment is characterized in that the mask setting unit 103 converts a theoretical bit error rate value in additive Gaussian noise to obtain an amplitude probability distribution mask to be set and an output unit 106 outputs and displays the amplitude probability distribution mask set by the conversion by the mask setting unit 103. Specifically, the third exemplary embodiment enables an amplitude probability distribution mask set by converting a bit error rate in Gaussian noise, which is frequency independent, rather than the acceptability of an allowed bit error rate with respect to an interference wave, to be used as a reference in electromagnetic interference wave measurement.

As illustrated in the characteristics diagram in FIG. 3 as the second exemplary embodiment, theoretically calculated values of bit error rates in additive Gaussian noise are known in various modulation schemes. However, the characteristic of an interference wave actually emitted from an object under measurement is usually non-Gaussian noise which is frequency dependent. For example, it is known that when an interference wave characteristic is impulsive, the bit error rate often significantly degrades, as compared with Gaussian noise of the same level of electric power.

In the third exemplary embodiment, an amplitude probability distribution mask that assumes additive Gaussian noise is presented to a user to allow the user to readily determine how much impact does an interference wave emitted from an object under measurement have on communications with respect to the impact of additive Gaussian noise.

### Fourth Exemplary Embodiment

An exemplary preferable configuration of an electromagnetic interference wave measurement device that is different from the configuration of the electromagnetic interference wave measurement device 100 illustrated in FIG. 1 will be described as a fourth exemplary embodiment of an electromagnetic interference wave measurement device including the function of displaying an amplitude probability distribution mask according to the present invention. The fourth exemplary embodiment is characterized by including a determination unit which compares values of an amplitude probability distribution mask set by conversion by a mask setting unit with values of an amplitude probability distribution of a measured interference wave.

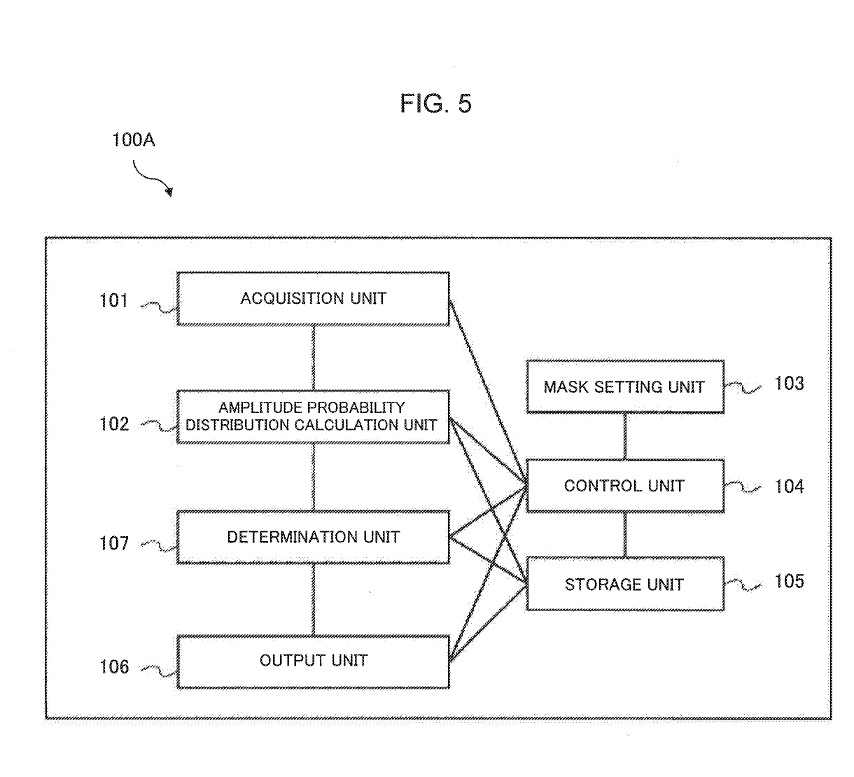

FIG. 5 is a block diagram illustrating an exemplary configuration of the fourth exemplary embodiment of an electromagnetic interference wave measurement device according to the present invention. The electromagnetic interference wave measurement device 100A illustrated in FIG. 5 includes a determination unit 107 in addition to the components of the electromagnetic interference wave measurement device 100 of the first exemplary embodiment illustrated in FIG. 1. The functional units of the electromagnetic interference measurement unit 100A except the determination unit 107 are the same as those of the electromagnetic interference measurement unit 100 in FIG. 1 and therefore, repeated description of those functional components will be omitted.

The determination unit 107 compares values of an electromagnetic interference wave amplitude probability distribution resulting from conversion by an amplitude probability distribution calculation unit 102 based on time-series measured data concerning an electromagnetic interference wave acquired by an acquisition unit 101 with values of an amplitude probability distribution mask set by conversion by a mask setting unit 103. If it is determined as a result of the comparison that the amplitude probability distribution of the electromagnetic interference wave overlaps the amplitude probability distribution mask, i.e. if a measured value of the amplitude probability distribution that is a result of measurement of the electromagnetic interference wave is greater than a mask value of the amplitude probability distribution mask indicating an allowable range, the determination unit 107 sends alarm information indicating that an error has been caused by the electromagnetic interference wave to the output unit 106. The output unit 106 outputs the amplitude probability distribution calculated by the amplitude probability distribution calculation unit 102 as the result of the measurement and the amplitude probability distribution mask calculated by the mask setting unit 103 based on an allowed bit error rate and, in addition, outputs the alarm information indicating the presence of the error (that a measured value of the amplitude probability distribution is greater than a mask value of the amplitude probability distribution mask) as the result of the determination by the determination unit 107.

In other words, the electromagnetic interference wave measurement device 100A according to the fourth exemplary embodiment can automate the determination as to whether an electromagnetic interference wave is acceptable with respect to an amplitude probability distribution mask based on the determination made by the determination unit 107. The user can readily see whether there is an error in a result of measurement (the amplitude probability distribution) with respect to the amplitude probability distribution mask based on the alarm information output from the output unit 106.

Note that the determination unit 107 may perform an operation to send a trigger signal described below to the output unit 106, instead of performing the operation to send the result of the determination indicating whether an error has occurred, i.e. alarm information, to the output unit 106 as described above.

The determination unit 107 sends a trigger signal for causing the output unit 106 to output an amplitude probability distribution and an amplitude probability distribution mask (and error information indicating occurrence of an error, if any) to the output unit 106 only when the determination unit 107 determines that an error in a result of measurement (the amplitude probability distribution) has occurred with respect to the amplitude probability distribution mask. When the determination unit 107 determines that no error has occurred, the determination unit 107 may not send the trigger signal to the output unit 106 and the output unit 106 may not display an amplitude probability distribution and an amplitude probability distribution mask. In that case, only when an electromagnetic interference wave that results in an error in an amplitude probability distribution with respect to an amplitude probability distribution mask is captured, the output unit 106 outputs at least the amplitude probability distribution, which is a result of measurement, and the amplitude probability distribution mask which indicates an allowable range.

### Other Exemplary Embodiments

The functional units of electromagnetic interference wave measurement device 100 in FIG. 1 and the electromagnetic interference wave measurement device 100A in FIG. 5 described above may be implemented by hardware alone as means for implementing the relevant functions, or such functions may be implemented as an electromagnetic interference wave measurement method by any implementation means or may be implemented by a combination of hardware and software. If the functions are implemented by a combination of hardware and software, a control program used for interference measurement is loaded onto a RAM (Random Access Memory), which is a program storage device, and hardware such as a control unit (CPU: Central Processing Unit) and the like is caused to operate based on operations of the control program to implement the functions as processing units (processing steps) equivalent to the functional units.

The control program described above can be stored on any of various types of non-transitory computer-readable media and provided to a computer. The non-transitory computer-readable media include various types of tangible storage media. Examples of the non-transitory computer-readable media include a magnetic recording medium (for example, a flexible disk, a magnetic tape, and a hard disk drive), a magneto-optical recording medium (for example, a magneto-optical disk), a CD-ROM (Read Only Memory) CD-R, a CD-R/W, a semiconductor memory (for example, a mask ROM, a PROM (Programmable ROM), an EPROM (Erasable PROM), a flash ROM, and a RAM (random Accesso Memory). The program may be provided to a computer using any of various types of transitory computer-readable media. Examples of transitory computer-readable media include an electrical signal, an optical signal, and an electromagnetic wave. The transitory computer-readable medium can provide the program to a computer through a wired communication path such as an electrical cable and optical fiber, or a wireless communication path. When the program is provided to a computer, the program is loaded onto a memory (RAM), which is a program storage device, and causes a control unit and other components to operate.

To put it another way, an information processing system that is to operate as an electromagnetic interference wave measurement device can be implemented by causing a control unit to execute, based on electromagnetic interference wave measurement program expanded on a RAM, processing steps such as an acquisition step equivalent to the function of the acquisition unit 101, an amplitude probability distribution calculation step equivalent to the function of the amplitude probability distribution calculation unit 102, a mask setting step equivalent to the function of the mask setting unit 103, a determination step equivalent to the function of the determination unit 107, and an output step equivalent to the function of the output unit 106 and operate. Such an information processing system can be built on a single personal computer, a server, or a cloud.

### INDUSTRIAL APPLICABILITY

The present invention can preferably be applied to a measurement device that estimates the impact of an electromagnetic interference wave on a wireless communication system in measurement and evaluation and environmental acceptability test of interference waves emitted from a common electronic device such as a household electric appliance. By using the electromagnetic interference wave measurement method according to the present invention, information for taking efficient measures against EMI can be obtained.

Configurations of preferred exemplary embodiments of the present invention have been described above. However, it should be noted that the exemplary embodiments are merely illustrative of the present invention and are not intended to limit the present invention. For example, it would be readily understood by those skilled in the art that modifications such as separating or combining block components, altering the sequence of steps, combining exemplary embodiments may be made as long as the spirit of the present invention and the functions described are met and that various variations and modifications are possible in accordance with a particular application without departing from the spirit of the present invention.

This application is based upon and claims the benefit of priority from Japanese Patent Application No. 2013-235651 filed on Nov. 14, 2013, the entire disclosure of which is incorporated herein.

### REFERENCE SIGNS LIST

10 Amplitude probability distribution mask
10A Amplitude probability distribution mask (MSK/BPSK/QPSK modulation scheme)
10B Amplitude probability distribution mask (16-QAM modulation scheme)
10C Amplitude probability distribution mask (64-QAM modulation scheme)
10D Amplitude probability distribution mask (256-QAM modulation scheme)
11 Amplitude probability distribution (IC under normal load)
12 Amplitude probability distribution (IC under high load)
100 Electromagnetic interference wave measurement device
100A Electromagnetic interference wave measurement device
101 Acquisition unit (acquisition means)
102 Amplitude probability distribution calculation unit (amplitude probability distribution measurement means)
103 Mask setting unit (mask setting means)
104 Control unit (control means)
105 Storage unit (storage means)
106 Output unit (output means)
107 Determination unit (determination means)

What is claimed is:

1. An electromagnetic interference wave measurement device which measures an electromagnetic interference wave emitted from an object under measurement and evaluates electromagnetic interference, the electromagnetic interference wave measurement device comprising:
a mask setting unit that converts a bit error rate allowed in an arbitrarily specified desired communication system into an amplitude probability distribution mask and setting the amplitude probability distribution mask resulting from the conversion;
an acquisition unit that collects time-series measured data concerning an electromagnetic interference wave being emitted from the object under measurement;
an amplitude probability distribution calculation unit that calculates an amplitude probability distribution relating to the electromagnetic interference wave based on the measured data collected by the acquisition unit at predetermined time intervals; and
an output unit that outputs the amplitude probability distribution mask set by the mask setting unit and the amplitude probability distribution calculated by the amplitude probability distribution calculation unit.

2. The electromagnetic interference wave measurement device according to claim 1,
wherein the mask setting unit sets one or a plurality of amplitude probability distribution masks obtained by converting a bit error rate or bit error rates in one or a plurality of different modulation schemes.

3. The electromagnetic interference wave measurement device according to claim 1,
wherein the bit error rate converted into the amplitude probability distribution mask by the mask setting unit is a theoretical bit error rate obtained on the assumption that an electromagnetic interference wave being emitted from the object under measurement is additive Gaussian noise.

4. The electromagnetic interference wave measurement device according to claim 1, further comprising a determination unit that compares values of the amplitude probability distribution calculated by the amplitude probability distribution calculation unit with values of the amplitude probability distribution mask set by the mask setting unit and, based on the comparison, sending alarm information indicating whether an error is present with respect to the amplitude probability distribution mask to the output unit,
wherein the output unit further outputs the alarm information received from the determination unit.

5. The electromagnetic interference wave measurement device according to claim 4,
wherein when the determination unit determines that the error has occurred, the determination unit sends, instead of the alarm information, a trigger signal for causing the output unit to output the amplitude probability distribution mask and the amplitude probability distribution to the output unit.

6. An electromagnetic interference wave measurement method for measuring an electromagnetic interference wave emitted from an object under measurement and evaluating electromagnetic interference, the electromagnetic interference wave measurement method comprising:
converting a bit error rate allowed in an arbitrarily specified desired communication system into an amplitude probability distribution mask and setting the amplitude probability distribution resulting from the conversion;
collecting time-series measured data concerning an electromagnetic interference wave being emitted from the object under measurement;
calculating an amplitude probability distribution indicating a result of measurement based on the measured data collected at predetermined time intervals; and
outputting the set amplitude probability distribution mask and the calculated amplitude probability distribution.

7. The electromagnetic interference wave measurement method according to claim 6,
wherein one or a plurality of amplitude probability distribution masks obtained by converting a bit error rate or bit error rates in one or a plurality of different modulation schemes are set.

8. The electromagnetic interference wave measurement method according to claim 6,
wherein the bit error rate converted into the amplitude probability distribution mask is a theoretical bit error rate obtained on the assumption that an electromagnetic interference wave being emitted from the object under measurement is additive Gaussian noise.

9. The electromagnetic interference wave measurement method according to claim 6, further comprising comparing values of the calculated amplitude probability distribution with values of the set amplitude probability distribution mask and, based on the comparison, sending out alarm information indicating whether an error is present with respect to the amplitude probability distribution mask,
wherein the amplitude probability distribution is output and the sent alarm information is further output.

10. A non-transitory computer-readable medium storing an electromagnetic interference wave measurement program for causing a computer to execute the electromagnetic interference wave measurement method according to claim 6.

11. The electromagnetic interference wave measurement device according to claim 2, further comprising a determination unit that compares values of the amplitude probability distribution calculated by the amplitude probability distribution calculation unit with values of the amplitude probability distribution mask set by the mask setting unit and, based on the comparison, sending alarm information indicating whether an error is present with respect to the amplitude probability distribution mask to the output unit,
wherein the output unit further outputs the alarm information received from the determination unit.

12. The electromagnetic interference wave measurement device according to claim 3, further comprising a determination unit that compares values of the amplitude probability distribution calculated by the amplitude probability distribution calculation unit with values of the amplitude probability distribution mask set by the mask setting unit and, based on the comparison, sending alarm information indicating whether an error is present with respect to the amplitude probability distribution mask to the output unit,
wherein the output unit further outputs the alarm information received from the determination unit.

13. The electromagnetic interference wave measurement device according to claim 11,
wherein when the determination unit determines that the error has occurred, the determination unit sends, instead of the alarm information, a trigger signal for causing the output unit to output the amplitude probability distribution mask and the amplitude probability distribution to the output unit.

14. The electromagnetic interference wave measurement device according to claim 12,
wherein when the determination unit determines that the error has occurred, the determination unit sends, instead of the alarm information, a trigger signal for causing the output unit to output the amplitude probability distribution mask and the amplitude probability distribution to the output unit.

15. The electromagnetic interference wave measurement method according to claim 7, further comprising comparing values of the calculated amplitude probability distribution with values of the set amplitude probability distribution mask and, based on the comparison, sending out alarm information indicating whether an error is present with respect to the amplitude probability distribution mask,
wherein the amplitude probability distribution is output and the sent alarm information is further output.

16. The electromagnetic interference wave measurement method according to claim 8, further comprising comparing values of the calculated amplitude probability distribution with values of the set amplitude probability distribution mask and, based on the comparison, sending out alarm information indicating whether an error is present with respect to the amplitude probability distribution mask,
wherein the amplitude probability distribution is output and the sent alarm information is further output.

17. A non-transitory computer-readable medium storing an electromagnetic interference wave measurement program for causing a computer to execute the electromagnetic interference wave measurement method according to claim 7.

18. A non-transitory computer-readable medium storing an electromagnetic interference wave measurement program for causing a computer to execute the electromagnetic interference wave measurement method according to claim 8.

19. A non-transitory computer-readable medium storing an electromagnetic interference wave measurement program for causing a computer to execute the electromagnetic interference wave measurement method according to claim 9.

20. A non-transitory computer-readable medium storing an electromagnetic interference wave measurement program for causing a computer to execute the electromagnetic interference wave measurement method according to claim 15.
